(19) United States
(12) Patent Application Publication
(10) Pub. No.: US 2005/0073221 A1
(43) Pub. Date: Apr. 7, 2005

(54) Device for converting mechanical energy into electrical energy

(75) Inventors: Andre Albsmeier, Munich (DE); Wolf-Eckhart Bulst, Munich (DE); Klaus Pistor, Linden (DE); Frank Schmidt, Zorneding (DE); Oliver Sczesny, Aschheim (DE)

Correspondence Address: COHEN, PONTANI, LIEBERMAN & PAVANE, 551 FIFTH AVENUE, SUITE 1210, NEW YORK, NY, 10176, US

(73) Assignee: EnOcean GmbH, Oberhaching (DE)

(21) Appl. No.: 10/495,018

(22) PCT Filed: Nov. 6, 2002
(86) PCT No.: PCT/DE02/04111

(30) Foreign Application Priority Data
Nov. 9, 2001 (DE) 101 55 125.8

(51) Int. Cl. H01L 41/113

(52) U.S. Cl. 310/339

(57) ABSTRACT

An apparatus for conversion of mechanical energy to electrical energy by means of a piezo transducer (1), on which an electrical voltage, which can be supplied to a load (8), is formed when deformation occurs. The piezo transducer (1) is formed from two or more layers (2) of piezoelectric material, which are separated from one another by electrically conductive layers (10, 11), and the successive electrically conductive layers (10, 11) are alternately connected to common electrical contacts (13, 14).

The invention relates to an apparatus for conversion of mechanical energy to electrical energy by means of a piezo transducer, on which an electrical voltage, which can be supplied to a load, is formed when deformation occurs. In an apparatus of this type which is known from WO 98/36395, an electrical voltage, which is produced by charge shifts in the piezoelectric material of the transducer, is generated by mechanical deformation of a piezo transducer. The known apparatus has a wire-free switch, which uses process energy, with radio signals, and this switch has a piezoelectric transducer to which finger pressure can be applied and which generates a piezo voltage. A code which corresponds to the ambient temperature can be applied to the radio-frequency signal that is produced by the switch. Furthermore, in order to generate a high piezo voltage, a mechanical operating apparatus with a beyond-dead-center spring can be used, which moves beyond the dead point when loaded, suddenly applying the selected mechanical prestress to the transducer.

The object of the invention is to provide an apparatus of the type mentioned initially which can be produced with relatively little effort for operation of a load, in particular of a load which contains a radio-frequency transmitter.

According to the invention, this object is achieved by the characterizing features of patent claim 1.

The invention provides an apparatus for conversion of mechanical energy, in particular in the form of available process energy, to electrical energy. The piezo transducer which is used for this purpose comprises two or more layers of piezoelectric material, which are separated from one another by electrically conductive layers. All the layers are mechanically firmly connected. The successive electrically conductive layers are alternately connected to common electrical contacts, which can if required be connected via supply lines to a load. The successive layers of the piezoelectric material preferably have rising layer thicknesses. The piezo transducer, which comprises two or more piezoelectric layers and the electrically conductive layers located in between them, can preferably be deformed by bending.

A deformation mechanism, which represents an invention in its own right, and has a mechanical energy store, in particular in the form of a spring element, may be used to deform the piezo transducer. The deformation mechanism may be designed such that the deformation movement during storage of the energy is greater than the deformation movement when the mechanical energy is being emitted to the piezo transducer. For this purpose, the deformation mechanism may be in the form of a lever mechanism, which allows the desired reduction in the movement distance to be achieved.

The spring element which forms the mechanical energy store may be designed such that the movement resulting from bending of the element from the rest position to the dead point is greater than the movement on the other side of the dead point after it has flipped over, on which the mechanical energy is emitted in order to deform the piezoelectric material. In this case, the forces behave in opposite senses, that is to say the force which acts on the piezo transducer is amplified by the same factor as the reduction in the movement distance. This effect is achieved not only in the case of a piezo transducer with the layer structure explained above, but in the case of any piezo transducer which can be deformed, in particular, by bending. The invention also discloses a deformation mechanism, in which a force acting on the piezo transducer and which is amplified by the factor of the movement distance reduction achieved by the lever effect is produced by the lever effect.

In order to achieve a compact design, the deformation mechanism and the piezo transducer may be arranged in a common holder. A supporting surface, on which the deformed piezo transducer rests, may be provided on the holder. This supporting surface may form an optimally preshaped substrate, against which the piezo transducer, which is deformed in particular by pressure when mechanical energy is being released, is pressed.

The mechanical energy is preferably introduced into the piezo transducer centrally on a surface of the piezo transducer. The piezo transducer can be mounted in or on the holder by clamping or adhesive bonding.

The load may likewise be arranged on or in the common holder. However, it is also possible to arrange the load remotely from the piezo transducer, and to supply the electrical voltage that is generated to the load via supply lines of appropriate size.

The load includes a transmitter, which is preferably operated by the converted energy, in particular a radio-frequency transmitter, by means of which information which is stored in electronics provided in the load or formed by evaluation, for example from measurement signals or sensor signals, is transmitted without the use of wires to a receiving station. For this purpose, the load may have a miniaturized circuit with a microprocessor and with the already mentioned transmitter, in particular a radio-frequency transmitter. When the piezo transducer is operated or deformed, the radio-frequency signal is transmitted. In addition to the already mentioned measurement or sensor information, this signal may include at least one identification number, a coding for safety applications, for example a rolling code method for electronic access and the like. The receiving station may be arranged remotely, and may contain the necessary devices for descrambling and evaluation of the transmitted information. These can be used for controlling processes, for indication and for storage or the like.

The invention may be used in widely differing fields. For example, the invention may be used for hand-operated switches which send their information by radio or via a wire link. Further application examples include electronic keys for cars, dwellings, commercial properties and the like. Furthermore, the invention may be used for status signaling devices for doors, windows and other objects. Furthermore, the invention can be used for switches in vehicles, such as automobiles and the like. Furthermore, the invention may be used for emergency call devices for personal protection, in hospitals, in public facilities such as train stations and the like. The invention is preferably used with mechanically operated sensors, in machine and plant construction and in vehicles, as well as in sports and recreational time appliances and toys.

Since the apparatus according to the invention can be implemented in a miniaturized form, it has a wide range of application options.

The invention will be explained in more detail using an exemplary embodiment and with reference to the figures, in which:

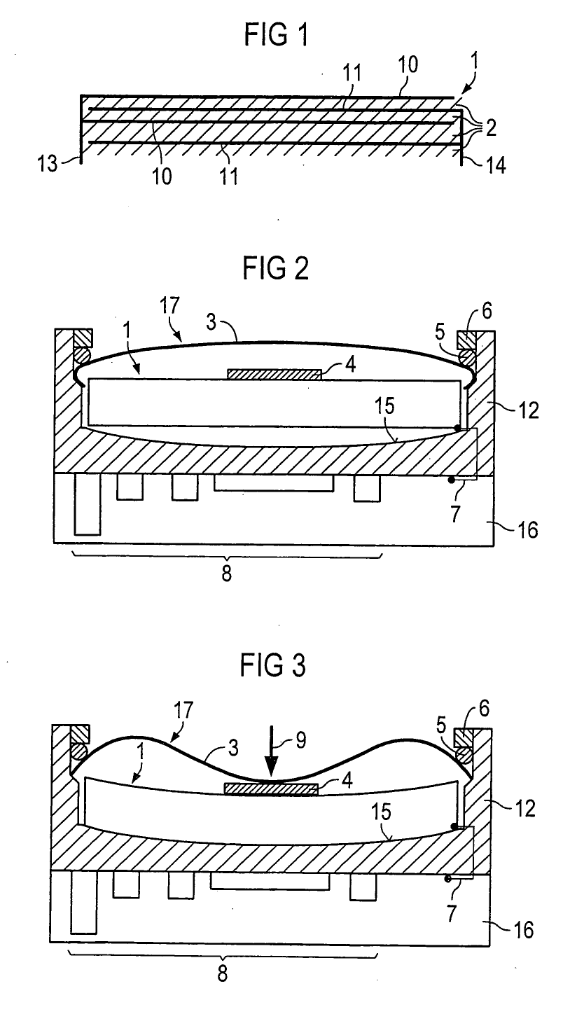

FIG. 1 shows a section through a piezo transducer which may be used for the invention;

FIG. 2 shows an illustration, in the form of a section, through an exemplary embodiment with the deformation mechanism in the rest state; and

FIG. 3 shows the state of the exemplary embodiment when mechanical energy is being emitted from the deformation mechanism to the piezo transducer.

The illustrated exemplary embodiment contains a piezo transducer 1 and a deformation mechanism 17, which transmits stored energy to the piezo transducer in order to deform it. The piezo transducer 1 is for this purpose inserted in a holder 12. The piezo transducer 1 is mounted, for example, by clamping or adhesive bonding on the edge zones of the piezo transducer.

The deformation mechanism 17 is arranged above the piezo transducer 1 and has a spring element 3 which, in the illustrated exemplary embodiment, is curved upwards in its rest position. The spring element 3 is mounted in the holder 2, which is in the form of a circular ring, by means of a mounting ring 6 and an elastic O-ring 5.

The spring element 3 forms a mechanical store which flexes when a mechanical pressure 9 is exerted from above or from outside, with mechanical energy in the process being stored up to a specific dead point of the deformation. Beyond the dead point of the deformation, the spring element 3 flips over to a state in which it is curved downwards, as illustrated in FIG. 3. In the process, it emits the stored mechanical energy to the piezo transducer 1, which is deformed in the process.

In the illustrated exemplary embodiment, a damping element 4 is provided at the point at which energy is transmitted to the piezo transducer 1. This results in a balanced load on the piezo transducer, as well as compensation for manufacturing tolerances. Furthermore, this results in the mechanical energy being transmitted to the piezo transducer 1 without causing damage.

The holder 12 is pot-shaped in the area in which it holds the piezo transducer 1 and the deformation mechanism 17, and has a supporting surface 15 on its base. The deformed piezo transducer 2 is pressed against this supporting surface 15. The curvature of the supporting surface 15 is matched to the optimum deformation of the piezo transducer 1. The optimum bent shape of the piezo transducer is designed with respect to the transducer protection and energy yield.

As is shown in FIGS. 2 and 3, the spring element 3 is supported on the holder via the O-ring 5 and the mounting ring 6 on the holder 12, at a distance from the point at which the mechanical energy is transmitted to the piezo transducer 1. This results in a lever effect, by means of which the stored mechanical energy is transmitted to the piezo transducer 1. This makes it possible for the deformation movement which the spring element 3 carries out after passing over the dead point when transmitting the stored mechanical energy to the piezo transducer 1 to be designed to be short, matching deformation of the piezo transducer that causes no damage. The lever effect results in an increased force being exerted on the piezoelectric material of the transducer 1. The deformation movement for bending of the spring element 3 from the rest position as illustrated in FIG. 2 to the dead point may advantageously be designed to be greater than the movement which takes place after flipping over or after passing over the dead point, when energy is being transmitted to the piezo transducer 1. This results in adequate transmission of the necessary mechanical energy, which is converted to electrical energy in the piezo transducer 1, with little deformation of the piezo transducer 1. The force which acts on the piezo transducer 1 is increased by the factor of the reduction in the movement distance which is achieved after the passing over the dead point position.

As can be seen from FIG. 1, a piezo transducer 1 with a layered structure is preferably used. The piezoelectric material, preferably composed of piezo ceramic, is arranged in layers 2 with a rising layer thickness. For the sake of simplicity, FIG. 1 shows three layers 2 of piezoelectric material. However, more layers may also be provided in the layer structure.

Separating layers in the form of electrically conductive layers 10, 11 are located between the layers 2 of piezoelectric material, in particular piezoelectric ceramic. Successive electrically conductive layers 10, 11 in the layer structure are alternately electrically connected to one another. This may be achieved by means of electrical contacts 13, 14, in a similar way to that in which contact is made with capacitor plates. In the illustrated exemplary embodiment, the electrically conductive separating layers 10 are connected to one another via the electrical contact 13, and the electrically conductive layers 11 are connected to one another via the electrical contact 14. The contact may be made, for example, by adhesive bonding, bonding, clamping or other contact-making methods.

In the case of the arrangement of the piezo transducer 1 installed in the holder 12, the layer 2 of piezoelectric material which has the least layer thickness is located on the side of the piezo transducer 1 on which the force is introduced when it is deformed by the deformation mechanism 17. As already mentioned, the layers 2 located underneath this have layer thicknesses which become ever greater in the sequence of the layer structure.

All of the layers in the layer structure are mechanically firmly connected to one another. The layered structure of the piezo transducer 1 results in a high energy density, and thus in a good miniaturization capability. A high degree of flexibility is available for the design of the mechanical and electrical parameters. The layered structure ensures that the piezo transducer has a long life and that it can be produced at low cost.

As can be seen in particular from FIGS. 2 and 3, the piezo transducer 1 with the layered structure may be used in such a way that central force introduction and bending in the central area are achieved, with support in the edge zones. This can be clearly seen in particular from the illustration in FIG. 3.

The piezo transducer 1 may be in the form of a circular disk and may be arranged in a holder 12 in the form of a circular ring. However, it is also possible to use a rectangular or square shape, in which the force is introduced centrally in the form of a line, in order to bend the piezo transducer 1.

In the illustrated exemplary embodiment, a miniaturized circuit is provided on the lower face of the holder 12, as the load 8. This circuit may have a microprocessor and a radio-frequency transmitter. The electrical voltage which is generated during deformation of the piezo transducer 1 is passed to the load 8 via electrical supply lines 7, one supply line of which is illustrated. During the deformation of the piezo transducer 1, the radio-frequency transmitter transmits a message which contains information, which is stored in the miniaturized circuit or has been obtained on activation by the voltage that is generated by the piezo transducer 1. This information may include at least one identification number, coding and measurement and/or sensor information and the like. The transmitted signals are received by a receiver station, which is provided remotely and is not illustrated in any more detail, and may be used to control processes, for indication and/or for storage. The load 8 may be enclosed by an encapsulation compound 16 or by some other suitable protective sheath.

1. An apparatus for conversion of mechanical energy to electrical energy by means of a piezo transducer (1), on which an electrical voltage, which can be supplied to a load (8), is formed when deformation occurs, characterized in that the piezo transducer (1) is formed from two or more layers (2) of piezoelectric material, which are separated from one another by electrically conductive layers (10, 11), and the successive electrically conductive layers (10, 11) are alternately connected to common electrical contacts (13, 14).

2. The apparatus as claimed in claim 1, characterized in that the successive layers (2) of the piezoelectric material have rising layer thicknesses.

3. The apparatus as claimed in claim 1, characterized in that the piezo transducer (1) is flexible.

4. (Canceled)

5. The apparatus, in particular as claimed in claim 1, characterized in that a deformation mechanism (17), which has a mechanical energy store (3, 5), is provided for deformation of the piezo transducer (1).

6. The apparatus as claimed in claim 5, characterized in that the deformation movement of the deformation mechanism (17) during the storage of mechanical energy is greater than when the mechanical energy is emitted to the piezo transducer (1).

7. The apparatus as claimed in claim 5, characterized in that the deformation mechanism (17) is in the form of a lever mechanism.

8. The apparatus as claimed in claim 5, characterized in that the energy store (5) has a spring element (3).

9. The apparatus as claimed in claim 8, characterized in that the spring element (3) has a dead point, with the spring element (3) storing mechanical energy when it is deformed on one side of the dead point, and emitting mechanical energy to the piezo transducer (1) on the other side of the dead point.

10. The apparatus as claimed in claim 1, characterized in that the mechanical energy is introduced into the piezo transducer (1) via a damping element (4).

11. The apparatus as claimed in claim 1, characterized in that the deformation mechanism (17) and the piezo transducer (1) are arranged in a common holder (12).

12. The apparatus as claimed in claim 1, characterized in that a supporting surface (15), on which the deformed piezo transducer (1) rests, is provided on the holder (12).

13. The apparatus as claimed in claim 1, characterized in that the mechanical energy is introduced centrally on a surface of the piezo transducer (1).

14. The apparatus as claimed in claim 1, characterized in that the layer (2) of the piezoelectric material with the least layer thickness is located on that side of the piezo transducer (1) on which the mechanical energy is introduced during the deformation of the piezo transducer.

15. The apparatus as claimed in claim 1, characterized in that the piezo transducer (1) is mounted on its edge zones in the holder (12) by means of clamping or adhesive bonding.

16. The apparatus as claimed in claim 1, characterized in that the load (8) is likewise arranged on or in the common holder (12).

17. The apparatus as claimed in claim 1, characterized in that the load (8) has a transmitter which is operated by the converted energy.

18. The apparatus as claimed in claim 17, characterized in that information which is transmitted by the transmitter has at least one identity number.
